(19) United States
(12) Patent Application Publication
(10) Pub. No.: US 2023/0090800 A1
(43) Pub. Date: Mar. 23, 2023

(54) MEMORY SYSTEM

(71) Applicant: Kioxia Corporation, Tokyo (JP)

(72) Inventor: Fuminori KIMURA, Kamakura (JP)

(73) Assignee: Kioxia Corporation, Tokyo (JP)

(21) Appl. No.: 17/644,430

(22) Filed: Dec. 15, 2021

(30) Foreign Application Priority Data
Sep. 22, 2021 (JP) 2021-154493

(51) Int. Cl. G11C 7/10; H01L 25/10; H01L 25/065; G11C 16/04; G11C 16/10; G11C 16/26; G06F 3/06

(52) U.S. Cl. CPC G11C 7/1048; H01L 25/105; H01L 25/0652; G11C 16/0483; G11C 16/10; G11C 16/26; G06F 3/0655; G06F 3/0604; G06F 3/0679; H01L 2225/06506; H01L 2225/06562; H01L 2225/06586

(57) ABSTRACT

According to one embodiment, a memory system includes: a first package including a first memory chip configured to store data, and a first chip containing a first circuit configured to control an On Die Termination (ODT) operation based on a first signal which is a control signal for reading of data stored in the first memory chip; a second package including a second memory chip configured to store data, and a second chip containing a second circuit configured to control the ODT operation based on the first signal, the first signal also being a control signal for reading of data stored in the second memory chip; and a controller configured to transmit the first signal to the first chip and the second chip.

### CROSS-REFERENCE TO RELATED APPLICATIONS

This application is based upon and claims the benefit of priority from Japanese Patent Application No. 2021-154493, filed Sep. 22, 2021, the entire contents of which are incorporated herein by reference.

### FIELD

Embodiments described herein relate generally to a memory system.

### BACKGROUND

A memory system including a nonvolatile memory and a memory controller that controls the nonvolatile memory has been known. The nonvolatile memory contains one or more memory chips. The memory controller and each memory chip contained in the nonvolatile memory are coupled to each other via a memory bus. In the nonvolatile memory, the On Die Termination (ODT) technique of providing the memory bus coupled to each memory chip with a termination resistor has been known. The ODT technique suppresses reflection of a signal in the memory bus.

### BRIEF DESCRIPTION OF THE DRAWINGS

FIG. 1 is a block diagram of a memory system according to a first embodiment.

FIG. 2 is a cross-sectional view of an example of a structure of the memory system according to the first embodiment.

FIG. 3 is a circuit diagram showing an example of a configuration of a memory bus in the memory system according to the first embodiment.

FIG. 4 is a circuit diagram showing an example of a configuration of an interface chip included in a package contained in the memory system according to the first embodiment.

FIG. 5 is a circuit diagram showing an example of a configuration of the package contained in the memory system according to the first embodiment.

FIG. 6 is a truth table showing an example of processing by a logic circuit included in the interface chip contained in the memory system according to the first embodiment.

FIG. 7 is a timing chart of a write operation in the memory system according to the first embodiment.

FIG. 8 is a timing chart of a read operation in the memory system according to the first embodiment.

FIG. 9 is a cross-sectional view of an example of a structure of a memory system according to a second embodiment.

FIG. 10 is a circuit diagram showing an example of a configuration of an interface chip included in a package contained in the memory system according to the second embodiment.

FIG. 11 is a circuit diagram showing an example of a configuration of the package contained in the memory system according to the second embodiment.

FIG. 12 is a circuit diagram showing an example of a configuration of a memory chip corresponding to the package contained in the memory system according to the second embodiment.

### DETAILED DESCRIPTION

In general, according to one embodiment, a memory system includes: a first package including a first memory chip configured to store data, and a first chip containing a first circuit configured to control an On Die Termination (ODT) operation based on a first signal which is a control signal for reading of data stored in the first memory chip; a second package including a second memory chip configured to store data, and a second chip containing a second circuit configured to control the ODT operation based on the first signal, the first signal also being a control signal for reading of data stored in the second memory chip; and a controller configured to transmit the first signal to the first chip and the second chip.

Hereinafter, embodiments will be described with reference to the drawings. For the description, common parts are assigned common reference numerals or symbols throughout the drawings.

### [1] First Embodiment

A memory system according to a first embodiment will be described.

[1-1] Configuration

[1-1-1] Configuration of Memory System

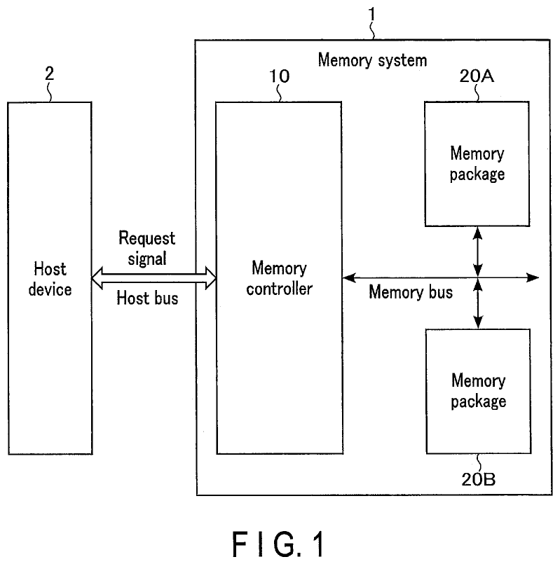

A configuration of a memory system according to the present embodiment will be described with reference to FIG. 1. FIG. 1 is a block diagram of the memory system according to the present embodiment.

A memory system 1 includes a memory controller 10 and memory packages (hereinafter, simply referred to as “packages”) 20A and 20B. The memory system 1 may further include a Dynamic Random Access Memory (DRAM) or a power supply circuit. The memory system 1 can be coupled to a host device 2. The memory system 1 performs processing based on a request signal received from the host device 2 or a voluntary processing request. Examples of the memory system 1 include a Solid State Drive (SSD), a Universal Flash Storage (UFS) device, a Universal Serial Bus (USB) memory, a Multi-Media Card (MMC), and SD™ card. Examples of the host device 2 include a personal computer, a server system, a mobile device, a vehicle-mounted device, and a digital camera.

The memory controller 10 is coupled to the host device 2 via a host bus. The memory controller 10 receives a request signal from the host device 2 via the host bus. The type of the host bus depends on an application applied to the memory system 1. In the case of the memory system 1 being a SSD, for the host bus, for example, an interface under Serial Attached SCSI (SAS), Serial ATA (SATA), or Peripheral Component Interconnect Express (PCIe™) standard is used. In the case of the memory system 1 being a UFS device, for the host bus, M-PHY standard is used. In the case of the memory system 1 being a USB memory, for the host bus, a USB standard is used. In the case of the memory system 1 being a MMC, for the host bus, an interface under the Embedded Multi Media Card (eMMC) standard is used. In the case of the memory system 1 being a SD™ card, for the host bus, an interface under the SD™ standard is used.

The memory controller 10 is coupled to each of the packages 20A and 20B via a memory bus. The memory controller 10 controls each of the packages 20A and 20B via the memory bus based on a request signal received from the host device 2 or a voluntary processing request. The memory bus transmits and receives signals compatible with a memory interface.

Each of the packages 20A and 20B includes an interface chip (hereinafter, referred to as “I/F chip”) and a plurality of memory chips. Details of the I/F chip and the memory chips will be described later. The number of packages included in the memory system 1 is not limited to two. The memory system 1 may include three or more (for example, four) packages.

[1-1-2] Structure of Memory System 1

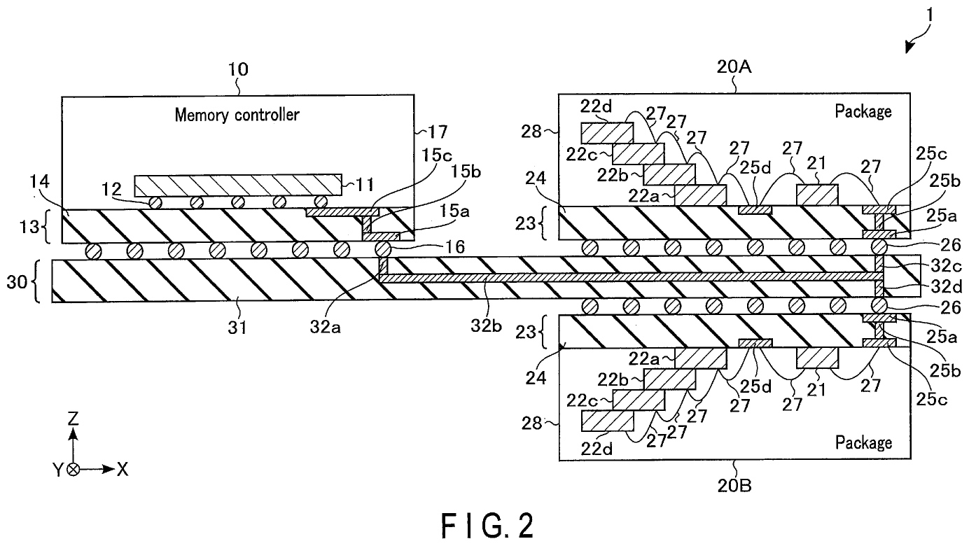

A structure of the memory system 1 according to the present embodiment will be described with reference to FIG. 2. FIG. 2 is a cross-sectional view of an example of a structure of the memory system 1 according to the present embodiment.

The memory system 1 further includes a Printed Circuit Board (PCB) (hereinafter, simply referred to as a “printed board”) 30. The printed board 30 includes a first surface and a second surface both formed in, for example, a rectangular shape and is formed in a rectangular parallelepiped shape or a plate shape. Hereinafter, the long-side direction of the first surface and the second surface of the printed board 30 will be referred to as an “X direction”. The short-side direction of the first surface and the second surface of the printed board 30 will be referred to as a “Y direction”. The direction in which the first surface and the second surface of the printed board 30 face each other will be referred to as a “Z direction”. Of two faces facing each other in the Z direction, the surface on the upper side of the sheet of FIG. 2 is defined as the first surface of the printed board 30, whereas the surface on the lower side of the sheet of FIG. 2 is defined as the second surface of the printed board 30.

First, the structures of the memory controller 10, the packages 20A and 20B, and the printed board 30 will be described.

The memory controller 10 includes an Integrated Circuit (IC) chip 11, a plurality of jointing materials (bumps) 12, a substrate 13, and a resin 17. Hereinafter, an example in which the substrate 13 is a Ball Grid Array (BGA) will be described; however, the substrate 13 may be a Pin Grid Array (PGA) or a Land Grid Array (LGA). The plurality of jointing materials 12 are joined to a surface of the substrate 13, and this surface will be referred to as the “first surface of the substrate 13”. A plurality of ball electrodes 16 to be described later are joined to a surface of the substrate 13, and this surface will be referred to as the “second surface of the substrate 13”.

The memory controller 10 has a structure of, for example, a System-on-a-Chip (SoC). Each of the jointing materials 12 and the ball electrodes 16 is a conductor material. One example of the ball electrodes 16 is a solder.

The substrate 13 includes a core material 14, a plurality of substrate wirings 15a, a plurality of substrate wirings 15b, and a plurality of substrate wirings 15c. To simplify the description, FIG. 2 illustrates one substrate wiring 15a, one substrate wiring 15b, and one substrate wiring 15c. The core material 14 is an insulator material. Each of the substrate wirings 15a to 15c is a conductor material. The substrate wirings 15a to 15c are provided in a portion of the core material 14. A portion of the substrate wiring 15a is exposed on the second surface of the substrate 13. A portion of the substrate wiring 15c is exposed on the first surface of the substrate 13. The substrate wiring 15b electrically couples the substrate wirings 15a and 15c together.

The plurality of jointing materials 12 are provided on the first surface of the substrate 13. The jointing materials 12 electrically couple the IC chip 11 and the substrate wirings 15c of the substrate 13 together. The substrate wirings 15a are provided on the second surface of the substrate 13. The substrate wirings 15a and the printed board 30 are electrically coupled together via the plurality of ball electrodes 16. That is, the jointing materials 12 are electrically coupled to the ball electrodes 16 via the substrate wirings 15a to 15c. In other words, the IC chip 11 electrically coupled (connected) to the printed board 30 via the jointing materials 12, the substrate wirings 15a to 15c, and the ball electrodes 16.

The resin 17 is, for example, epoxy resin. The first surface of the substrate 13, the plurality of jointing materials 12, and the IC chip 11 are covered with the resin 17.

Each of the packages 20A and 20B includes an I/F chip 21, a plurality of memory chips 22 (22a to 22d), a substrate 23, a plurality of interconnects 27, and a resin 28. The package 20B has a similar configuration to that of the package 20A. Thus, the package 20A will be described hereinafter. The example in which the substrate 23 is a BGA will be described hereinafter, however, the substrate 23 may be a PGA or LGA. The I/F chip 21 is joined to a surface of the substrate 23, and this surface will be referred to as the “first surface of the substrate 23”. A plurality of ball electrodes 26 to be described later are joined to a surface of the substrate 23, and this surface will be referred to as the “second surface of the substrate 23”. Each of the ball electrodes 26 is a conductor material. One example of the ball electrodes 26 is a solder.

The I/F chip 21 controls communications between the memory controller 10 and the plurality of memory chips 22. Each of the memory chips 22 is, for example, a NAND flash memory.

The substrate 23 includes a core material 24, a plurality of substrate wirings 25a, a plurality of substrate wirings 25b, a plurality of substrate wirings 25c, and a plurality of substrate wirings 25d. To simplify the description, FIG. 2 illustrates one substrate wiring 25a, one substrate wiring 25b, one substrate wiring 25c, and one substrate wiring 25d. The core material 24 is an insulator material. Each of the substrate wirings 25a to 25d is a conductor material. The substrate wirings 25a to 25d are provided in a portion of the core material 24. The substrate wirings 25a are partially exposed on the second surface of the substrate 23. The substrate wirings 25c and 25d are partially exposed on the first surface of the substrate 23. The substrate wirings 25b electrically couples the substrate wirings 25a and 25c together, respectively. Each of the substrate wirings 25d functions as a pad for relaying, which electrically couples the I/F chip 21 to the memory chips 22a to 22d.

The substrate wirings 25a are provided on the second surface of the substrate 23. The substrate wirings 25a and the printed board 30 are electrically coupled together via the plurality of ball electrodes 26.

The I/F chip 21 and the stacked memory chips 22a to 22d are provided on the first surface of the substrate 23. The memory chips 22a to 22d are electrically coupled via the interconnects 27. The interconnects 27 are illustrated as being wire-bonded, however, wire bonding may be replaced with, for example, a technique such as through-silicon via (TSV).

Each of the plurality of interconnects 27 is a conductor material. The I/F chip 21 is coupled to the substrate wiring 25c of the substrate 23 via the interconnect 27. The I/F chip 21 is coupled to the substrate wiring 25d of the substrate 23 via the interconnect 27. The memory chip 22a is coupled to the substrate wiring 25d via the interconnect 27. The memory chip 22b is coupled to the memory chip 22a via the interconnect 27. The memory chip 22c is coupled to the memory chip 22b via the interconnect 27. The memory chip 22d is coupled to the memory chip 22c via the interconnect 27. Therefore, the memory chips 22a to 22d are electrically coupled to the printed board 30 via the interconnects 27, the substrate wirings 25a to 25d, and the I/F chip 21.

The resin 28 is, for example, epoxy resin. The first surface of the substrate 23, the I/F chip 21, the memory chips 22a to 22d, and the interconnects 27 are covered with the resin 28.

The number of memory chips in the package 20A is not limited to four. Two, three, or five or more memory chips may be provided inside the package 20A. The same applies to the number of memory chips inside the package 20B.

The printed board 30 includes a core material 31, a plurality of substrate wirings 32a, a plurality of substrate wirings 32b, a plurality of substrate wirings 32c, and a plurality of substrate wirings 32d. To simplify the description, FIG. 2 illustrates one substrate wiring 32a, one substrate wiring 32b, one substrate wiring 32c, and one substrate wiring 32d. The core material 31 is an insulator material. Each of the substrate wirings 32a to 32d is a conductor material. The substrate wirings 32a to 32d are provided in a portion of the core material 31. The substrate wirings 32a and 32c are partially exposed on the first surface of the printed board 30. The substrate wirings 32d are partially exposed on the second surface of the printed board 30. The substrate wirings 32b electrically couple the substrate wirings 32a, 32c, and 32d together, respectively.

Next, coupling between the printed board 30 and each of the memory controller 10, the package 20A, and the package 20B will be described.

The memory controller 10 is provided on the first surface of the printed board 30 via the plurality of ball electrodes 16. The ball electrode 16 jointed to the substrate wiring 15a of the substrate 13 is jointed to the substrate wiring 32a of the printed board 30.

The package 20A is provided on the first surface of the printed board 30 via the plurality of ball electrodes 26. The ball electrode 26 jointed to the substrate wiring 25a of the substrate 23 of the package 20A are jointed to the substrate wiring 32c of the printed board 30.

The package 20B is provided on the second surface of the printed board 30 via the plurality of ball electrodes 26. The ball electrode 26 jointed to the substrate wiring 25a of the substrate 23 of the package 20B are jointed to the substrate wiring 32d of the printed board 30.

Through the coupling described in the above, the memory controller 10 is electrically coupled to each of the packages 20A and 20B. In other words, the IC chip 11 is electrically coupled to the memory chip 22 via the I/F chip 21. In FIG. 2, the packages 20A and 20B are provided with the printed board 30 sandwiched therebetween; however, the packages 20A and 20B may be each provided on the first surface of the printed board 30 or may be each provided on the second surface of the printed board 30. Furthermore, the inner structures of the packages 20A and 20B may be symmetric with respect to a point in the printed board 30. That is, on each of the first surface and the second surface of the printed board 30, the memory chip 22 may be arranged on the left side as viewed from the printed board 30 and the I/F chip 21 may be arranged on the right side, or the other way around.

[1-1-3] Circuit Configuration of Memory Bus

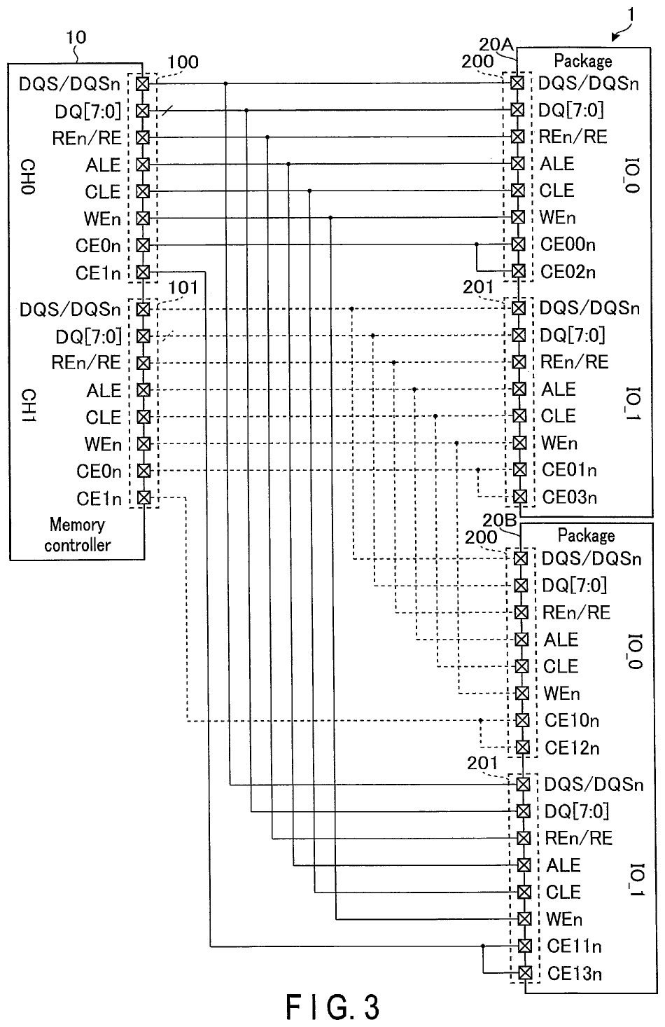

A circuit configuration of the memory bus in the memory system 1 according to the present embodiment will be described with reference to FIG. 3. FIG. 3 is a circuit diagram showing an example of the memory bus in the memory system 1 according to the present embodiment.

In the present embodiment, the memory controller 10 includes, for example, two channels CH (hereinafter, referred to as a “channel CH0” and a “channel CH1”) in order to transmit and receive signals to and from the packages 20A and 20B. The channels CH0 and CH1 are respectively coupled to different memory buses. The memory controller 10 includes an input/output pin group 100 corresponding to the channel CH0 and an input/output pin group 101 corresponding to the channel CH1. Each of the packages 20A and 20B includes two input/output pin groups 200 and 201 respectively corresponding to two channels CH. For example, in the example shown in FIG. 3, the input/output pin group 200 of the package 20A and the input/output pin group 201 of the package 20B are coupled to the channel CH0. The input/output pin group 201 of the package 20A and the input/output pin group 200 of the package 20B are coupled to the channel CH1. The channel CH0 may be coupled to the input/output pin groups 200 of the packages 20A and 20B and the channel CH1 may be coupled to the input/output pin groups 201 of the packages 20A and 20B, or the channels CH0 and CH1 may be coupled vice versa. Hereinafter, a signal group transmitted through the input/output pin group 200 will be referred to as a “signal IO_0” and a signal group transmitted through the input/output pin group 201 will be referred to as a “signal IO_1”. The signal IO_0 or signal IO_1 is input/output to/from each of the memory chips 22 in the packages 20A and 20B. The memory controller 10 may include three or more channels CH. In the case where the number of packages is five or more, each of the packages may be coupled to a channel CH other than the channels CH0 and CH1 included in the memory controller 10. In the case where the number of packages is five or more, three or more packages may be coupled to each of the channels CH0 and CH1.

Examples of a signal transferred through a memory bus contain a chip enable signal CEn, an input/output signal DQ, a command latch enable signal CLE, an address latch enable signal ALE, a write enable signal WEn, read enable signals REn and RE, and data strobe signals DQS and DQSn.

The signal CEn is a signal to enable a corresponding memory chip 22. The signal CEn is asserted at, for example, a Low (“L”) level. The term “assert” means that a signal (or logic) is in a valid (active) state.

The signals CEn that are respectively transmitted from the channels CH0 and CH1 to the packages 20A and 20B are independently controlled. Hereinafter, the signal CEn corresponding to the memory chips 22 in the package 20A will be referred to as a signal “CE0n”, and the signal CEn corresponding to the memory chips 22 in the package 20B will be referred to as a signal “CE1n”.

The signal CE0n transmitted from the channel CH0 is divided into two signals (hereinafter, referred to as signals “CE00n” and “CE02n”). The package 20A receives the signal CE0n as two signals CE00n and CE02n. Among the plurality of memory chips 22 included in the package 20A, each of the signals CE00n and CE02n is transmitted to a memory chip 22 corresponding to the signal IO_0.

The signal CE1n transmitted from the channel CH0 is divided into two signals (hereinafter, referred to as a “signal CE11n” and a “signal CE13n”). The package 20B receives the signal CE1n as two signals CE11n and CE13n. Among the plurality of memory chips 22 included in the package 20B, each of the signals CE11n and CE13n is transmitted to a memory chip 22 corresponding to the signal IO_1.

The signal CE0n transmitted from the channel CH1 is divided into two signals (hereinafter, referred to as a “signal CE01n” and a “signal CE03n”). The package 20A receives the signal CE0n as two signals CE01n and CE03n. Among the plurality of memory chips 22 included in the package 20A, each of the signals CE01n and CE03n is transmitted to a memory chip 22 corresponding to the signal IO_1.

The signal CE1n transmitted from the channel CH1 is divided into two signals (hereinafter, referred to as a “signal CE10n” and a “signal CE12n”). The package 20B receives the signal CE1n as two signals CE10n and CE12n. Among the plurality of memory chips 22 included in the package 20B, each of the signals CE10n and CE12n is transmitted to a memory chip 22 corresponding to the signal 100.

The input/output signal DQ is, for example, an 8-bit signal (hereinafter, simply referred to as a “signal DQ” or a “signal DQ[7:0]”). The signal DQ is data transmitted and received between the corresponding memory chip 22 and the memory controller 10. The signal DQ includes a command, an address, write data, read data, and status information.

The signal CLE is a signal indicating that the signal DQ is a command. The signal CLE is asserted at, for example, a High (“H”) level. The signal ALE is a signal indicating that the signal DQ is an address. The signal ALE is asserted at, for example, the “H” level.

The signal WEn is a signal for the corresponding memory chip 22 to fetch the received signal DQ. The corresponding memory chip 22 fetches the signal DQ based on a rising edge or falling edge of the signal WEn.

The signals REn and RE are each a signal for the memory controller 10 to read data from the corresponding memory chip 22. The signal REn is an inversion signal of the signal RE. The corresponding memory chip 22 generates the signal DQS based on the signals REn and RE, and outputs the signal DQ to the memory controller 10 based on the generated signal DQS.

When the memory controller 10 transmits a write command to the corresponding memory chip 22, the signal REn is set to the “H” level by the memory controller 10, and the signal RE is set to the “L” level by the memory controller 10. When the memory controller 10 transmits a read command to the corresponding memory chip 22, the signal REn is set to the “L” level by the memory controller 10, and the signal RE is set to the “H” level by the memory controller 10.

The signals CLE, ALE, WEn, REn, and RE transmitted from one channel CH are transmitted to each of the packages 20A and 20B.

The signals DQS and DQSn are used to control timing of transmitting and receiving the signal DQ. The signal DQSn is an inversion signal of the signal DQS. For example, when data is written, the signals DQS and DQSn are transmitted together with the write data DQ from the memory controller 10 to the corresponding memory chip 22. The corresponding memory chip 22 receives the write data DQ in synchronization with the signals DQS and DQSn. When data is read, the signals DQS and DQSn are transmitted together with the read data DQ from the corresponding memory chip 22 to the memory controller 10. When data is read, the signals DQS and DQSn are generated based on the signal REn. The memory controller 10 receives the read data DQ in synchronization with the signals DQS and DQSn.

Each of the input/output pin groups 100 and 101 includes a plurality of signal pins. Hereinafter, a signal pin used for transferring the signals DQS and DQSn will be referred to as a “DQS pin”. The signals DQS and DQSn are transferred using different DQS pins, respectively. However, FIG. 3 illustrates one DQS pin in order to simplify the description. The signal pin used for transferring the signals DQ[7:0] will be referred to as a “DQ pin”. The signals DQ[7:0] are transferred using different DQ pins, respectively. However, FIG. 3 illustrates one DQ pin in order to simplify the description. The signal pin used for transferring the signals REn and RE will be referred to as an “RE pin”. The signals REn and RE are transferred using different RE pins, respectively. However, FIG. 3 illustrates one RE pin in order to simplify the description. The signal pin used for transferring the signal ALE will be referred to as an “ALE pin”. The signal pin used for transferring the signal CLE will be referred to as a “CLE pin”. The signal pin used for transferring the signal WEn will be referred to as a “WE pin”. The signal pin used for transferring the signal CE0n will be referred to as a “first CE pin”. The signal pin used for transferring the signal CE1n will be referred to as a “second CE pin”.

Each of the input/output pin groups 200 and 201 in the package 20A contains a plurality of signal pins. The plurality of signal pins in each of the input/output pin groups 200 and 201 in the package 20A include a DQS pin, a DQ pin, an RE pin, an ALE pin, a CLE pin, and a WE pin, as with the input/output pin groups 100 and 101 of the memory controller 10. In the input/output pin group 200, a signal pin used for transferring the signal CE00n will be referred to as a “first CE pin”. In the input/output pin group 200, a signal pin used for transferring the signal CE02n will be referred to as a “second CE pin”. In the input/output pin group 201, a signal pin used for transferring the signal CE01n will be referred to as a “first CE pin”. In the input/output pin group 201, a signal pin used for transferring the signal CE03n will be referred to as a “second CE pin”.

Each of the input/output pin groups 200 and 201 in the package 20B contains a plurality of signal pins. The plurality of signal pins included in each of the input/output pin groups 200 and 201 in the package 20B include a DQS pin, a DQ pin, an RE pin, an ALE pin, a CLE pin, and a WE pin, as with the input/output pin groups 100 and 101 of the memory controller 10. In the input/output pin group 200, a signal pin used for transferring the signal CE10n will be referred to as a “first CE pin”. In the input/output pin group 200, a signal pin used for transferring the signal CE12n will be referred to as a “second CE pin”. In the input/output pin group 201, a signal pin used for transferring the signal. CE11n will be referred to as a “first CE pin”. In the input/output pin group 201, a signal pin used for transferring the signal CE13n will be referred to as a “second CE pin”.

The DQS pin, the DQ pin, the RE pin, the ALE pin, the CLE pin, and the WE pin of the input/output pin group 100 are respectively coupled to the DQS pin, the DQ pin, the RE pin, the ALE pin, the CLE pin, and the WE pin of the input/output pin group 200 in the package 20A. The DQS pin, the DQ pin, the RE pin, the ALE pin, the CLE pin, and the WE pin of the input/output pin group 100 are respectively coupled to the DQS pin, the DQ pin, the RE pin, the ALE pin, the CLE pin, and the WE pin of the input/output pin group 201 in the package 20B.

The first CE pin of the input/output pin group 100 is coupled to each of the first CE pin and the second CE pin of the input/output pin group 200 in the package 20A. The second CE pin of the input/output pin group 100 is coupled to each of the first CE pin and the second CE pin of the input/output pin group 201 in the package 20B.

The DQS pin, the DQ pin, the RE pin, the ALE pin, the CLE pin, and the WE pin of the input/output pin group 101 are respectively coupled to the DQS pin, the DQ pin, the RE pin, the ALE pin, the CLE pin, and the WE pin of the input/output pin group 201 in the package 20A. The DQS pin, the DQ pin, the RE pin, the ALE pin, the CLE pin, and the WE pin of the input/output pin group 101 are respectively coupled to the DQS pin, the DQ pin, the RE pin, the ALE pin, the CLE pin, and the WE pin of the input/output pin group 200 in the package 20B.

The first CE pin of the input/output pin group 101 is coupled to each of the first CE pin and the second CE pin of the input/output pin group 201 in the package 20A. The second CE pin of the input/output pin group 101 is coupled to each of the first CE pin and the second CE pin of the input/output pin group 200 in the package 20B.

[1-1-4] Circuit Configuration of I/F Chip 21

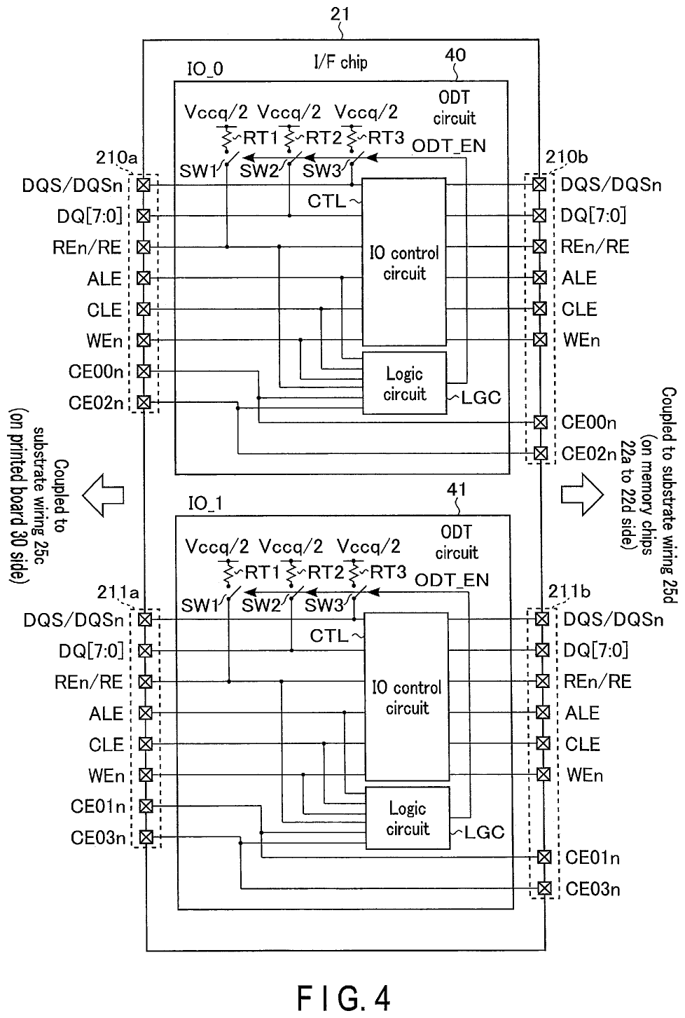

A circuit configuration of the I/F chips 21 respectively included in the packages 20A and 20B contained in the memory system 1 according to the present embodiment will be described with reference to FIG. 4. FIG. 4 is a circuit diagram showing an example of a configuration of the I/F chip 21 included in the package 20A contained in the memory system 1 according to the present embodiment. The I/F chip 21 included in the package 20B has a similar configuration to that of the I/F chip 21 in the package 20A. Thus, a configuration of the I/F chip 21 in the package 20A will be described hereinafter.

The I/F chip 21 contains input/output pin groups 210a, 210b, 211a, and 211b, and On Die Termination (ODT) circuits 40 and 41.

Hereinafter, a case in which the package 20A contains memory chips 22a to 22d corresponding to the signal IO_0 and memory chips 22a to 22d corresponding to the signal IO_1 will be described. The memory chips 22a to 22d corresponding to the signal IO_0 in the package 20A are the memory chips 22a to 22d coupled to the input/output pin group 210b of the I/F chip 21 in the package 20A, for example. The memory chips 22a to 22d corresponding to the signal IO_1 in the package 20A are the memory chips 22a to 22d coupled to the input/output pin group 211b of the I/F chip 21 in the package 20A, for example. Details of the input/output pin groups 210b and 211b of the I/F chip 21 will be described later.

The input/output pin groups 210a and 210b are pin groups corresponding to the signal IO_0. Each of the input/output pin groups 210a and 210b includes a plurality of signal pins. The plurality of signal pins in each of the input/output pin groups 210a and 210b include a DQS pin, a DQ pin, an RE pin, an ALE pin, a CLE pin, a WE pin, a first CE pin, and a second CE pin, as with the input/output pin group 200 in the package 20A. The plurality of signal pins of the input/output pin group 210a are coupled to the input/output pin group 200 in the package 20A. In the input/output pin group 210a, a signal pin used for transferring the signal CE00n will be referred to as a “first CE pin”. In the input/output pin group 210a, a signal pin used for transferring the signal CE02n will be referred to as a “second CE pin”. The plurality of signal pins of the input/output pin group 210b are respectively couple to the memory chips 22a to 22d corresponding to the signal IO_0. In the input/output pin group 210b, the signal pin used for transferring the signal CE00n will be referred to as a “first CE pin”. In the input/output pin group 210b, the signal pin used for transferring the signal CE02n will be referred to as a “second CE pin”.

The input/output pin groups 211a and 211b are pin groups corresponding to the signal IO_1. Each of the input/output pin groups 211a and 211b includes a plurality of signal pins. The plurality of signal pins in each of the input/output pin groups 211a and 211b include a DQS pin, a DQ pin, an RE pin, an ALE pin, a CLE pin, a WE pin, a first CE pin, and a second CE pin, as with the input/output pin group 201 in the package 20A. The plurality of signal pins of the input/output pin group 211a are coupled to the input/output pin group 201 in the package 20A. In the input/output pin group 211a, the signal pin used for transferring the signal CE01n will be referred to as a “first CE pin”. In the input/output pin group 211a, the signal pin used for transferring the signal CE03n will be referred to as a “second CE pin”. The plurality of signal pins of the input/output pin group 211b are respectively coupled to the memory chips 22a to 22d corresponding to the signal IO_1. In the input/output pin group 211b, the signal pin used for transferring the signal CE01n will be referred to as a “first CE pin”. In the input/output pin group 211b, the signal pin used for transferring the signal CE03n will be referred to as a “second CE pin”.

The CDT circuit 40 controls, by using a termination resistor, reflection of a signal occurring between the IC chip 11 of the memory controller 10 and the input/output pin group 210a of the I/F chip 21 in the package 20A when a signal is input/output. The ODT circuit 41 controls, by using a termination resistor, reflection of a signal occurring between the IC chip 11 of the memory controller 10 and the input/output pin group 211a of the I/F chip 21 in the package 20A when a signal is input/output.

Hereinafter, “coupling (terminating) at least one signal pin of the input/output pin group 210a to the termination resistor” will also be expressed as “turning on the ODT circuit of the I/F chip” or “executing the ODT operation by the ODT circuit of the I/F chip”. On the other hand, “not coupling (not terminating) any signal pin of the input/output pin group 210a to the termination resistor” will also be expressed as “turning off or not turning on the ODT circuit of the I/F chip” or “not executing the ODT operation by the ODT circuit of the I/F chip”. The same expression will be used for the input/output pin group 211a, too.

The ODT circuit 40 is a circuit corresponding to the signal IO_0. The ODT circuit 40 is coupled to the plurality of signal pins of the input/output pin group 210a and to the plurality of signal pins of the input/output pin group 210b. The ODT circuit 41 is a circuit corresponding to the signal IO_1. The ODT circuit 41 is coupled to the plurality of signal pins of the input/output pin group 211a and to the plurality of signal pins of the input/output pin group 211b. Each of the ODT circuits 40 and 41 includes an IO control circuit CTL, a logic circuit LGC, a plurality of switches SW1, a plurality of switches SW2, a plurality of switches SW3, a plurality of resistance elements RT1, a plurality of resistance elements RT2, and a plurality of resistance elements RT3. To simplify the description, FIG. 4 illustrates one switch SW1, one switch SW2, one switch SW3, one resistance element RT1, one resistance element RT2, and one resistance element RT3. The ODT circuit 41 has a similar configuration to that of the ODT circuit 40. Thus, the ODT circuit 40 will be described hereinafter.

The IO control circuit CTL is coupled to the DQS pin, the DQ pin, the RE pin, the ALE pin, the CLE pin, and the WE pin of the input/output pin group 210a, and to the DQS pin, the DQ pin, the RE pin, the ALE pin, the CLE pin, and the WE pin of the input/output pin group 210b. The IO control circuit CTL receives the signals DQS, DQSn, DQ, REn, RE, ALE, CLE, and WEn from the input/output pin group 210a. The IO control circuit CTL adjusts a waveform of received signals. The IC control circuit CTL transmits each of the adjusted signals to the input/output pin group 210b. The IO control circuit CTL receives the signals DQS, DQSn, and DQ from the input/output pin group 210b. The IO control circuit CTL transmits the adjusted signals DQS, DQSn, and DQ to the input/output pin group 210a.

The logic circuit LGC is an operation circuit. The logic circuit LGC is coupled to the RE pin, the ALE pin, the CLE pin, the WE pin, the first CE pin, and the second CE pin of the input/output pin group 210a. The logic circuit LGC receives the signals REn, RE, ALE, CLE, WEn, CE00n, and CE02n from the input/output pin group 210a. The logic circuit LGC performs a logic operation based on a signal received from the input/output pin group 210a. The logic circuit LGC outputs an operation result as an ODT enable signal ODT_EN (hereinafter, also simply referred to as a “signal ODT_EN”) to the plurality of switches SW1 to SW3. The signal ODT_EN is a signal indicating whether to turn on the ODT circuit 40 of the I/F chip 21. The signal ODT_EN is set to the “H” level when, for example, the ODT circuit 40 is turned on. The logic circuit LGC includes circuits such as, for example, an AND circuit, an OR circuit, a NAND circuit, a NOR circuit, and an EX-OR circuit. The logic circuit LGC performs a logic operation on a received signal by using these circuits in combination. Details of the processing by the logic circuit LGC will be described later.

The signal CE00n is transferred between the first CE pin of the input/output pin group 210a and the first CE pin of the input/output pin group 210b. The signal CE02n is transferred between the second CE pin of the input/output pin group 210a and the second CE pin of the input/output pin group 210b.

Each of the plurality of switches SW1 to SW3 is a switching element controlled based on the signal ODT_EN. Each of the switches SW1 to SW3 may be constituted by a transistor. Each of the plurality of resistance elements RT1 to RT3 functions as a termination resistor. A resistance value of each of the plurality of resistance elements RT1 to RT3 may be a fixed value or may be switched to a given value. In the case of switching to a given value, switching can be performed by, for example, transmitting a specific command from the memory controller 10 to the I/F chip 21 and by following setting of a register (not shown) of the I/F chip 21.

On end of the switch SW1 is coupled to the RE pin of the input/output pin group 210a. The other end of the switch SW1 is coupled to one end of the resistance element RT1. A voltage Vccq/2 is applied to the other end of the resistance element RT1. The voltage Vccq is, for example, a potential of a power source, which is supplied to the I/F chip 21 of the package 20A.

One end of the switch SW2 is coupled to the DQ pin of the input/output pin group 210a. The other end of the switch SW2 is coupled to one end of the resistance element RT2. A voltage Vccq/2 is applied to the other end of the resistance element RT2.

One end of the switch SW3 is coupled to the DQS pin of the input/output pin group 210a. The other end of the switch SW3 is coupled to one end of the resistance element RT3. A voltage Vccq/2 is applied to the other end of the resistance element RT3.

In the case of the signal ODT_EN being at the “H” level, each of the switches SW1 to SW3 is turned on (turned to an ON state (a coupled state)). By the switch SW1 being turned to the ON state, the RE pin of the input/output pin group 210a is terminated. By the switch SW2 being turned to the ON state, the DQ pin of the input/output pin group 210a is terminated. By the switch SW3 being turned to the ON state, the DQS pin of the input/output pin group 210a is terminated. That is, during a period in which the signal ODT_EN is at the “H” level, the ODT circuit 40 of the I/F chip 21 is turned on. In other words, in the case of the signal ODT_EN being at the “H” level, the ODT circuit 40 of the I/F chip 21 executes the ODT operation. On the other hand, in the case of the signal ODT_EN being at the “L” level, each of the switches SW1 to SW3 is turned off (turned to an OFF state (a decoupled state)). By each of the switches SW1 to SW3 being turned to the OFF state, each of the RE pin, the DQ pin, and the DQS pin of the input/output pin group 210a is not terminated. That is, during a period in which the signal ODT_EN is at the “L” level, the ODT circuit 40 of the I/F chip 21 is not turned on. In other words, in the case of the signal ODT_EN being at the “L” level, the ODT circuit 40 of the I/F chip 21 does not execute the ODT operation.

Signal pins to be terminated are not limited to the DQS pin, the DQ pin, and the RE pin. As a termination method for the I/F chip 21, a method optimized for a toggle frequency of the signals DQS and DQSn, for example, a Center Tapped Termination (CTT) or Pseudo Open Drain (POD) can be selected. In the case of adopting the POD, the memory chip 22 may be provided with a Vref training function to find an optimal Vref level with respect to the memory chip 22 by including an internal reference voltage Vref generator in the I/F chip 21, performing Write training with the memory controller 10, and generating a result of pass/failure every time the inner reference voltage Vref is varied and scanned.

[1-1-5] Circuit Configuration of Package 20A

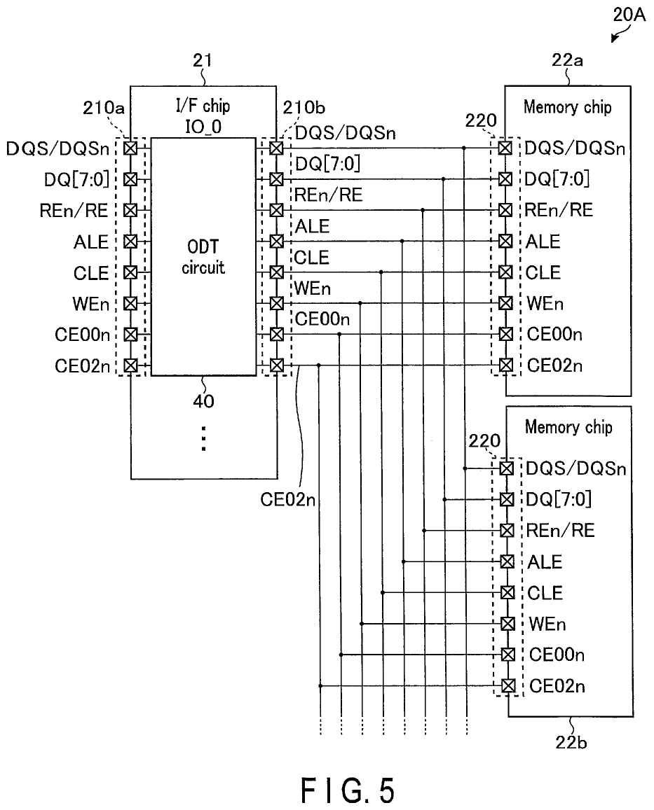

A circuit configuration of the package 20A included in the memory system 1 according to the present embodiment will be described with reference to FIG. 5. FIG. 5 is a circuit diagram showing an example of a configuration of the package 20A contained in the memory system 1 according to the present embodiment. FIG. 5 omits the memory chips 22c and 22d coupled to the ODT circuit 40 included in the I/F chip 21 contained in the package 20A. FIG. 5 omits the input/output pin groups 211a and 211b, and the ODT circuit 41 of the I/F chip 21. FIG. 5 also omits the memory chips 22a to 22d coupled to the ODT circuit 41. The package 20B has a similar circuit configuration to that of the package 20A. Thus, a circuit configuration of the package 20A will be described hereinafter.

Each of the memory chips 22a to 22d includes an input/output pin group 220. The input/output pin group 220 includes a plurality of signal pins. The plurality of signal pins in the input/output pin group 220 include a DQS pin, a DQ pin, an RE pin, an ALE pin, a CLE pin, a WE pin, a first CE pin, and a second CE pin, as with the input/output pin group 210b in the I/F chip 21. In the input/output pin group 220, a signal pin used for transporting the signal CE00n will be referred to as a “first CE pin”. In the input/output pin group 220, a signal pin used for transporting the signal CE02n will be referred to as a “second CE pin”.

The DQS pin, the DQ pin, the RE pin, the ALE pin, the CLE pin, the WE pin, the first CE pin, and the second CE pin of the input/output pin group 210b are respectively coupled to the DQS pin, the DQ pin, the RE pin, the ALE pin, the CLE pin, the first CE pin, and the second CE pin of the input/output pin group 220 in the memory chip 22a.

Coupling between the input/output pin group 210b and the input/output pin group 220 of the memory chip 22b is similar to coupling between the input/output pin group 210b and the input/output pin group 220 of the memory chip 22a. Coupling between the input/output pin group 210b and the input/output pin group 220 of the memory chip 22c, and coupling between the input/output pin group 210b and the input/output pin group 220 of the memory chip 22d are similar to coupling between the input/output pin group 210b and the input/output pin group 220 of the memory chip 22a.

[1-1-6] Processing by Logic Circuit LGC

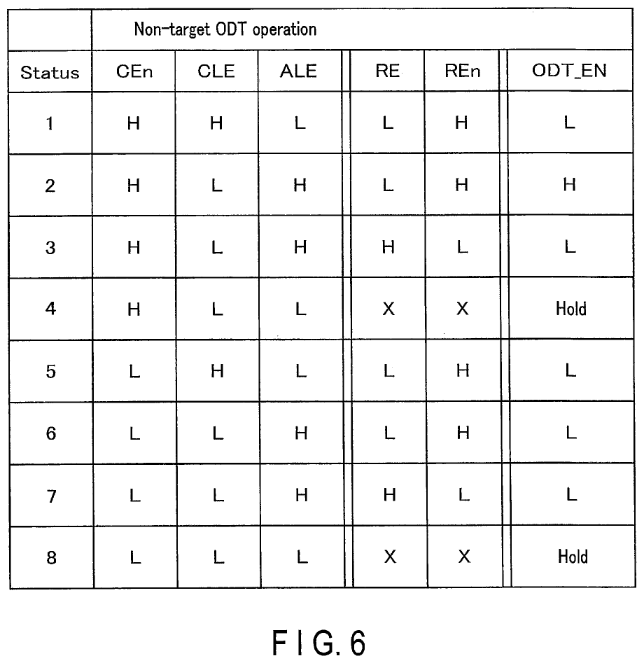

Processing by the logic circuit LGC included in the I/F chip 21 contained in the memory system 1 according to the present embodiment will be described with reference to FIG. 6. FIG. 6 is a truth table showing an example of processing by the logic circuit LGC included in the I/F chip 21 contained in the memory system 1 according to the present embodiment.

Hereinafter, processing by the logic circuit LGC will be described by giving an example in which the memory system 1 performs a non-target ODT operation when performing a write operation or a read operation. Through this description, “non-target ODT operation” means that the ODT circuit is turned on in the I/F chip 21 of a package to which the memory controller 10 does not access (does not select or does not consider as an access target).

The logic circuit LGC performs a logic operation based on one of the statuses 1 to 8 in FIG. 6. In FIG. 6, the signal CEn is one of the signals CE00n, CE01n, CE02n, CE03n, CE10n, CE11n, CE12n, and CE13n. The logic circuit LGC holds a status if it is other than the statuses 1 to 8.

In the case of the status 1, the signal CEn is at the “H” level, the signal CLE is at the “H” level, the signal ALE is at the “L” level, the signal RE is at the “L” level, and the signal REn is at the “H” level (the first line of the truth table in FIG. 6). That is, the status 1 indicates a status in which in a command sequence of the read operation or the write operation, a command is transmitted and the corresponding memory chip 22 is not selected.

In the case of the status 1, the logic circuit LGC determines that the present status corresponds to a non-selected side in the non-target ODT operation. The non-selected side indicates a path coupled to the memory chip 22 that is not an access target. The logic circuit LGC sets the signal ODT_EN to the “L” level. In this manner, the ODT circuit on the non-selected side in the I/F chip 21 is not turned on.

In the case of the status 2, the signal CEn is at the “H” level, the signal CLE is at the “L” level, the signal ALE is at the “H” level, the signal RE is at the “L” level, and the signal REn is at the “H” level (the second line of the truth table in FIG. 6). That is, the status 2 indicates a status in which in a command sequence of the write operation, an address is transmitted and the corresponding memory chip 22 is not selected.

In the case of the status 2, the logic circuit LGC determines that the present status corresponds to the write operation being in progress and the side being a non-selected side. The logic circuit LGC sets the signal ODT_EN to the H″ level. In this manner, the ODT circuit on the non-selected side in the I/F chip 21 is turned on.

In the case of the status 3, the signal CEn is at the “H” level, the signal CLE is at the “L” level, the signal ALE is at the “H” level, the signal RE is at the “H” level, and the signal REn is at the “L” level (the third line of the truth table in FIG. 6). That is, the status 3 indicates a status in which in a command sequence of the read operation, an address is transmitted and the corresponding memory chip 22 is not selected.

In the case of the status 3, the logic circuit LGC determines that the present status corresponds to the read operation being in progress and the side being a non-selected side. The logic circuit LGC sets the signal ODT_EN to the “L” level. In this manner, the ODT circuit on the non-selected side in the I/F chip 21 is not turned on. However, the I/F chip 21 may be configured as ASIC, and when Read is determined, a different logic operation from that of Write may be performed to turn on the ODT circuit on the non-selected side in the I/F chip 21.

In the case of the status 4, the signal CEn is at the “H” level, the signal CLE is at the “L” level, the signal ALE is at the “L” level, the signal RE is at the “H” or “L” level, and the signal REn is at the “L” or “H” level (the fourth line of the truth table in FIG. 6).

In the case of the status 4, the logic circuit LGC holds a status. The logic circuit LGC holds the signal ODT_EN in the status 2 or 3 until a transition is made to the status 1 or 5. That is, the ODT circuit on the non-selected side in the I/F chip 21 maintains the ON state or OFF state.

In the case of the status 5, the signal CEn is at the “L” level, the signal CLE is at the “H” level, the signal ALE is at the “L” level, the signal RE is at the “L” level, and the signal REn is at the “H” level (the fifth line of the truth table in FIG. 6). That is, the status 5 indicates a status in which in a command sequence of the write operation or the read operation, a command is transmitted and the corresponding memory chip 22 is selected.

In the case of the status 5, the logic circuit LGC determines that the present status corresponds to a selected side in the non-target ODT operation. The selected side indicates a path coupled to the memory chip 22 that is an access target. The logic circuit LGC sets the signal ODT_EN to the “L” level. In this manner, the ODT circuit on the selected side in the I/F chip 21 is not turned on.

In the case of the status 6, the signal CEn is at the “L” level, the signal CLE is at the “L” level, the signal ALE is at the “H” level, the signal RE is at the “L” level, and the signal REn is at the “H” level (the sixth line of the truth table in FIG. 6). That is, the status 6 indicates a status in which in a command sequence of the write operation, an address is transmitted and the corresponding memory chip 22 is selected.

In the case of the status 6, the logic circuit LGC determines that the present status corresponds to the write operation being in progress and the side being a selected side. The logic circuit LGC sets the signal ODT_EN to the “L” level. In this manner, the ODT circuit on the selected side in the I/F chip 21 is not turned on.

In the case of the status 7, the signal CEn is at the “L” level, the signal CLE is at the “L” level, the signal ALE is at the “H” level, the signal RE is at the “H” level, and the signal REn is at the “L” level (the seventh line of the truth table in FIG. 6). That is, the status 7 indicates a status in which in a command sequence of the read operation, an address is transmitted and the corresponding memory chip 22 is selected.

In the case of the status 7, the logic circuit LGC determines that the present status corresponds to the read operation being in progress and the side being a selected side. The logic circuit LGC sets the signal ODT_EN to the “L” level. In this manner, the ODT circuit on the selected side in the I/F chip 21 is not turned on.

In the case of the status 8, the signal CEn is at the “L” level, the signal CLE is at the “L” level, the signal ALE is at the “L” level, the signal RE is at the “H” or “L” level, and the signal REn is at the “L” or “H” level (the eighth line of the truth table in FIG. 6).

In the case of the status 8, the logic circuit LGC holds a status. The logic circuit LGC holds the signal ODT_EN in the status 6 or 7 until a transition is made to the status 1 or 5. That is, the ODT circuit on the selected side in the I/F chip 21 maintains the ON state or OFF state.

[1-2] Non-Target ODT Operation

The memory system 1 according to the present embodiment performs a non-target ODT operation. The following will describe a case in which in the channel CH0, the memory controller 10 accesses one of the memory chips 22a to 22d corresponding to the signal IO_0 of the package 20A, and does not access the memory chips 22a to 22d corresponding to the signal IO_1 of the package 20B. In other words, the following will describe a case in which the ODT circuit 40 of the I/F chip 21 in the package 20A corresponds to a selected side and the ODT circuit 41 of the I/F chip 21 in the package 20B corresponds to a non-selected side.

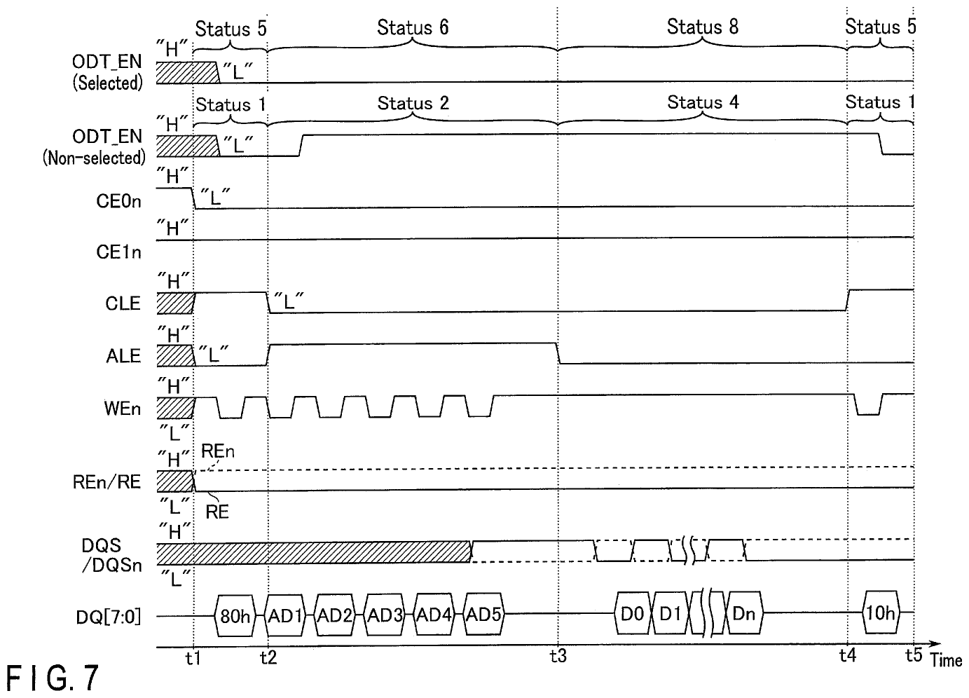

First, the non-target ODT operation when performing the write operation will be described with reference to FIG. 7. FIG. 7 is a timing chart of the write operation accompanied with the non-target ODT operation in the memory system 1 according to the present embodiment. The shaded part in FIG. 7 indicates a value not defined in particular.

At time t1, the memory controller 10 sets the signal CE0n to the “L” level in the channel CH0. In this manner, one of the memory chips 22a to 22d corresponding to the signal IO_0 in the package 20A becomes a selected-state target. The memory controller 10 sets the signal CE1n to the “H” level. After this, the memory controller 10 maintains the signal CE1n at the “H” level. In this manner, each of the memory chips 22a to 22d corresponding to the signal IO_1 in the package 20B becomes a non-selected state. The memory controller 10 sets the signal CLE to the “H” level. The memory controller 10 sets the signal ALE to the “L” level. The memory controller 10 sets the signal REn to the “H” level. The memory controller 10 sets the signal RE to the “L” level.

During a period from time t1 to time t2, the memory controller 10 transmits a write command 80h as the signal DQ to each of the packages 20A and 20B. The signal WEn is toggled in accordance with the signal DQ.

During a period from time t1 to time t2, a signal input to the package 20A on a selected side is in the status 5 shown in FIG. 6. Therefore, the logic circuit LGC of the ODT circuit 40 in the package 20A sets the signal ODT_EN to the “L” level. It suffices that a timing when the signal ODT_EN is set to the “L” level falls within a period from time t1 to time t2. By this, each of the switches SW1 to SW3 of the ODT circuit 40 is turned to the OFF state. As a result, each of the DQS pin, the DQ pin, and the RE pin of the input/output pin group 210a of the I/F chip 21 in the package 20A is not terminated. That is, the ODT circuit 40 of the I/F chip 21 is not turned on in the package 20A.

During a period from time t1 to time t2, a signal input to the package 20B on a non-selected side is in the status 1 shown in FIG. 6. Therefore, the logic circuit LGC of the ODT circuit 41 in the package 20B sets the signal ODT_EN to the “L” level. It suffices that a timing when the signal ODT_EN is set to the “L” level falls within a period from time t1 to time t2. By this, each of the switches SW1 to SW3 of the ODT circuit 41 is turned to the OFF state. As a result, each of the DQS pin, the DQ pin, and the RE pin of the input/output pin group 211a of the I/F chip 21 in the package 20B is not terminated. That is, the ODT circuit 41 of the I/F chip 21 is not turned on in the package 20B.

At time t2, the memory controller 10 sets the signal CLE to the “L” level and the signal ALE to the “H” level.

During a period from time t2 to time t3, the memory controller 10 transmits addresses AD1 to AD5 (for example, a five-cycle address signal) as the signal DQ to each of the packages 20A and 20B. The signal WEn is toggled in accordance with the signal DQ.

During a period from time t2 to time t3, a signal input to the package 20A on a selected side is in the status 6 shown in FIG. 6. Therefore, the logic circuit LGC of the ODT circuit 40 in the package 20A sets the signal ODT_EN to the “L” level. It suffices that a timing when the signal ODT_EN is set to the “L” level falls within a period from time t2 to time t3. As a result, the ODT circuit 40 of the I/F chip 21 is not turned on in the package 20A.

During a period from time t2 to time t3, a signal input to the package 20B on a non-selected side is in the status 2 shown in FIG. 6. Therefore, the logic circuit LGC of the ODT circuit 41 in the package 20B sets the signal ODT_EN to the “H” level. It suffices that a timing when the signal ODT_EN is set to the “H” level falls within a period from time t2 to time t3. By this, each of the switches SW1 to SW3 of the ODT circuit 41 is turned to the ON state. As a result, each of the DQS pin, the DQ pin, and the RE pin of the input/output pin group 211a of the I/F chip 21 in the package 20B is terminated. That is, the ODT circuit 41 of the I/F chip 21 is turned on in the package 20B.

At time t3, the memory controller 10 sets the signal ALE to the “L” level.

During a period from time t3 to time t4, the memory controller 10 transmits data D0 to Dn (where n is an integer equal to or greater than 1) as the signal DQ to each of the packages 20A and 20B. The signals DQS and DQSn are toggled in accordance with the signal DQ.

During a period from time t3 to time t4, a signal input to the package 20A on a selected side is in the status 8 shown in FIG. 6. Therefore, the logic circuit LGC of the ODT circuit 40 in the package 20A maintains the signal ODT_EN at the “L” level. That is, the ODT circuit 40 of the I/F chip 21 maintains the OFF state in the package 20A.

During a period from time t3 to time t4, a signal input to the package 20B on a non-selected side is in the status 4 shown in FIG. 6. Therefore, the logic circuit LGC of the ODT circuit 41 in the package 20B maintains the signal ODT_EN at the “H” level. That is, the ODT circuit 41 of the I/F chip 21 maintains the ON state in the package 20B.

At time t4, the memory controller 10 sets the signal CLE to the “H” level.

During a period from t4 to t5, the memory controller 10 transmits a write execution command 10h as the signal DQ to each of the packages 20A and 20B. The signal WEn is toggled in accordance with the signal DQ.

During a period from time t4 to time t5, a signal input to the package 20A on a selected side is in the status 5 shown in FIG. 6. Therefore, the logic circuit LGC of the ODT circuit 40 in the package 20A sets the signal ODT_EN to the “L” level. It suffices that a timing when the signal ODT_EN is set to the “L” level falls within a period from time t4 to time t5. As a result, the ODT circuit 40 of the I/F chip 21 is not turned on in the package 20A.

During a period from time t4 to time t5, a signal input to the package 20B on a non-selected side is in the status 1 shown in FIG. 6. Therefore, the logic circuit LGC of the ODT circuit 41 in the package 20B sets the signal ODT_EN to the “L” level. It suffices that a timing when the signal ODT_EN is set to the “L” level falls within a period from time t4 to time t5. As a result, the ODT circuit 41 of the I/F chip 21 is turned off in the package 20B.

The logic circuit LGC of the ODT circuit 40 in the package 20A may set the signal ODT_EN to the “L” level in response to, for example, the signal CE0n transitioning from the “H” level to the “L” level. In this case also, in the package 20A, the ODT circuit 40 of the I/F chip 21 is turned off.

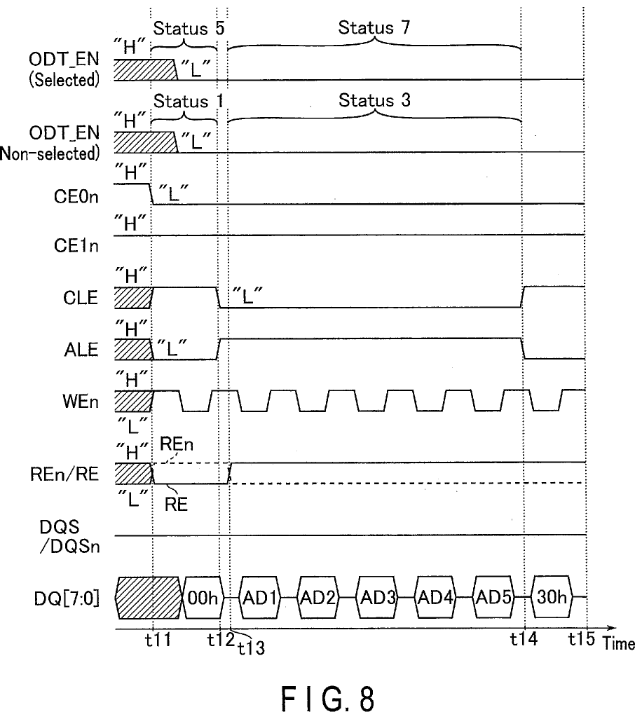

Next, the non-target ODT operation when performing the read operation will be described with reference to FIG. 8. FIG. 8 is a timing chart of the read operation not accompanied with the non-target ODT operation in the memory system 1 according to the present embodiment. The shaded part in FIG. 8 indicates a value not defined in particular.

At time t11, the memory controller 10 sets the signal CE0n to the “L” level in the channel CH0. In this manner, one of the memory chips 22a to 22d corresponding to the signal IO_0 in the package 20A becomes a selected-state target. The memory controller 10 sets the signal CE1n to the “H” level. After this, the memory controller 10 maintains the signal CE1n at the “H” level. In this manner, each of the memory chips 22a to 22d corresponding to the signal IO_1 in the package 20B becomes a non-selected state. The memory controller 10 sets the signal CLE to the “H” level. The memory controller 10 sets the signal ALE to the “L” level. The memory controller 10 sets the signal REn to the “H” level. The memory controller 10 sets the signal RE to the “L” level.

During a period from t11 to time t12, the memory controller 10 transmits a read command 00h as the signal DQ to each of the packages 20A and 20B. The signal WEn is toggled in accordance with the signal DQ.

During a period from time t11 to time t12, a signal input to the package 20A on a selected side is in the status 5 shown in FIG. 6. Therefore, the logic circuit LGC of the ODT circuit 40 in the package 20A sets the signal ODT_EN to the “L” level. It suffices that a timing when the signal ODT_EN is set to the “L” level falls within a period from time t11 to time t12. As a result, the ODT circuit 40 of the I/F chip 21 is not turned on in the package 20A.

During a period from time t11 to time t12, a signal input to the package 20B on a non-selected side is in the status 1 shown in FIG. 6. Therefore, the logic circuit LGC of the ODT circuit 41 in the package 20B sets the signal ODT_EN to the “L” level. It suffices that a timing when the signal ODT_EN is set to the “L” level falls within a period from time t11 to time t12. As a result, the ODT circuit 41 of the I/F chip 21 is not turned on in the package 20B.

At time t12, the memory controller 10 sets the signal CLE to the “L” level and the signal ALE to the “H” level.

At time t13, the memory controller 10 sets the signal REn to the “L” level and the signal RE to the “H” level.

During a period from time t13 to time t14, the memory controller 10 transmits addresses AD1 to AD5 (for example, a five-cycle address signal) as the signal DQ to each of the packages 20A and 20B. The signal WEn is toggled in accordance with the signal DQ.

During a period from time t13 to time t14, a signal input to the package 20A on a selected side is in the status 7 shown in FIG. 6. Therefore, the logic circuit LGC of the ODT circuit 40 in the package 20A sets the signal ODT_EN to the “L” level. It suffices that a timing when the signal ODT_EN is set to the “L” level falls within a period from time t13 to time t14. As a result, the ODT circuit 40 of the I/F chip 21 is not turned on in the package 20A.

During a period from time t13 to time t14, a signal input to the package 20B on a non-selected side is in the status 3 shown in FIG. 6. Therefore, the logic circuit LGC of the ODT circuit 41 in the package 20B sets the signal ODT_EN to the “L” level. It suffices that a timing when the signal ODT_EN is set to the “L” level falls within a period from time t13 to time t14. As a result, the ODT circuit 41 of the I/F chip 21 is not turned on in the package 20B.

At time t14, the memory controller 10 sets the signal CLE to the “H” level and the signal ALE to the “L” level.

During a period from t14 to t15, the memory controller 10 transmits read execution command 30h as the signal DQ to each of the packages 20A and 20B. The signal WEn is toggled in accordance with the signal DQ.

During a period from time t14 to time t15, a signal input to the package 20A on a selected side is not in any of the statuses 1 to 8 shown in FIG. 6. Therefore, the logic circuit LGC of the ODT circuit 40 in the package 20A maintains the signal ODT_EN at the “L” level. That is, the ODT circuit 40 of the I/F chip 21 maintains the OFF state in the package 20A.

During a period from time t14 to time t15, a signal input to the package 20B on a non-selected side is not in any of the statuses 1 to 8 shown in FIG. 6. Therefore, the logic circuit LGC of the ODT circuit 41 in the package 20B maintains the signal ODT_EN at the “L” level. That is, the ODT circuit 41 of the I/F chip 21 maintains the OFF state in the package 20B.

In the channel CH0, the non-target ODT operation in a case in which the ODT circuit 40 of the I/F chip 21 in the package 20A corresponds to a non-selected side and the ODT circuit 41 of the I/F chip 21 in the package 20B corresponds to a selected side is executed in a similar manner. In this case, the ODT circuit 40 of the I/F chip 21 is turned on in the package 20A during a period in which the data D0 to Dn is transferred as at least the signal DQ during the write operation. During the write operation, in the package 20B, the ODT circuit 41 of the I/F chip 21 is not turned on. During the read operation, both the ODT circuit 40 of the I/F chip 21 in the package 20A and the ODT circuit 41 of the I/F chip 21 in the package 20B are not turned on.

In the channel CH1, the non-target ODT operation in a case in which the ODT circuit 41 of the I/F chip 21 in the package 20A corresponds to a selected side and the ODT circuit 40 of the I/F chip 21 in the package 20B corresponds to a non-selected side is executed in a similar manner. In this case, during the write operation, in the package 20A, the ODT circuit 41 of the I/F chip 21 is not turned on. The ODT circuit 40 of the I/F chip 21 is turned on in the package 20B during a period in which the data DO to Dn is transferred as at least the signal DQ during the write operation. During the read operation, both the ODT circuit 41 of the I/F chip 21 in the package 20A and the ODT circuit 40 of the I/F chip 21 in the package 20B are not turned on.

In the channel CH1, the non-target ODT operation in a case in which the ODT circuit 41 of the I/F chip 21 in the package 20A corresponds to a non-selected side and the ODT circuit 40 of the I/F chip 21 in the package 20B corresponds to a selected side is executed in a similar manner. In this case, the ODT circuit 41 of the I/F chip 21 is turned on in the package 20A during a period in which the data D0 to Dn is transferred as at least the signal DQ during the write operation. During the write operation, in the package 20B, the ODT circuit 40 of the I/F chip 21 is not turned on. During the read operation, both the ODT circuit 41 of the I/F chip 21 in the package 20A and the ODT circuit 40 of the I/F chip 21 in the package 20B are not turned on.

[1-3] Advantageous Effect

The memory system 1 according to the present embodiment is provided with two packages 20A and 20B. Each of the packages 20A and 20B contains the I/F chip 21 and the plurality of memory chips 22. The I/F chip 21 includes an ODT circuit. The ODT circuit controls an ODT operation in the I/F chip 21. The ODT circuit of the I/F chip 21 is turned on with respect to the package to which the memory controller 10 does not access during the write operation. This configuration suppresses reflection of a signal from the package that the memory controller 10 does not access. Accordingly, operation reliability of the memory system 1 can be improved.

In the memory system 1 according to the present embodiment, the memory controller 10 controls the signals RE and REn in order to control the ODT circuit of the I/F chip 21. The ODT circuit of the I/F chip 21 is turned on or off based on the signals RE and REn. Therefore, the memory controller 10 does not necessarily issue a specific command for turning on or off the ODT circuit of the I/F chip 21. This can reduce a command overhead. Accordingly, this can enhance the speed of operations of the memory system 1.

### [2] Second Embodiment

The second embodiment will be described. A memory system 1A according to the present embodiment includes packages 20AA and 20AB. The second embodiment differs from the first embodiment in terms of a structure of the packages 20AA and 20AB, a circuit configuration of an I/F chip 21A, a circuit configuration of the packages 20AA and 20AB, and a circuit configuration of memory chips 22A (22Aa to 22Ad). The following description will in principle concentrate on the features different from the first embodiment.

[2-1] Structure of Packages 20AA and 20AB

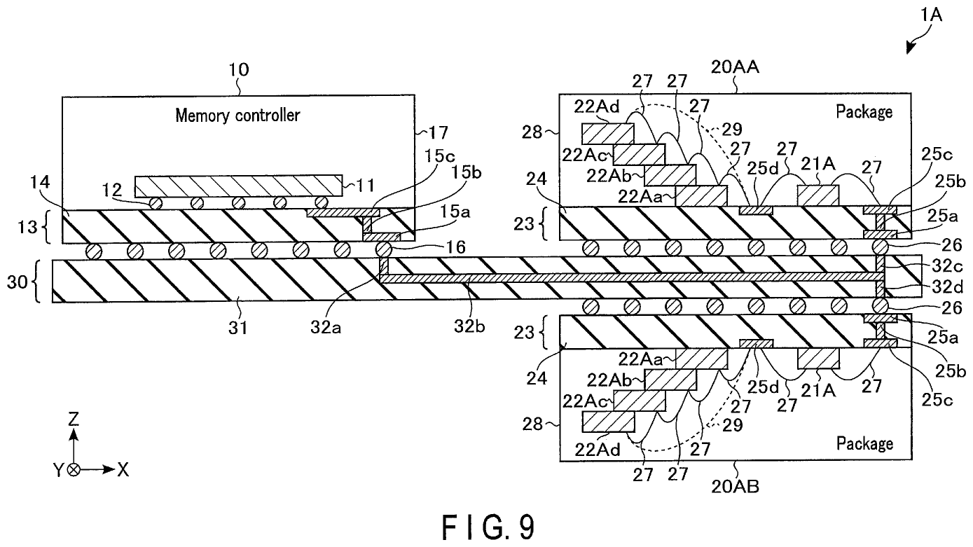

A structure of the packages 20AA and 20AB included in the memory system 1A according to the present embodiment will be described with reference to FIG. 9. FIG. 9 is a cross-sectional view of an example of a structure of the memory system 1A according to the present embodiment.

Each of the packages 20AA and 20AB further includes an interconnect 29 in addition to the configuration of the packages 20A and 20B according to the first embodiment. The interconnect 29 is used to transfer an ODT enable signal ODT_EN (hereinafter, also simply referred to as a “signal ODT_EN”) from the I/F chip 21A to the memory chip 22Ad. The memory chip 22Ad is coupled to the substrate wiring 25d via the interconnects 29. The rest of the structure of the packages 20AA and 20AB is similar to that of the first embodiment. The structure of the memory controller 10 and the printed board 30 is similar to that of the first embodiment.

[2-2] Circuit Configuration of I/F Chip 21A

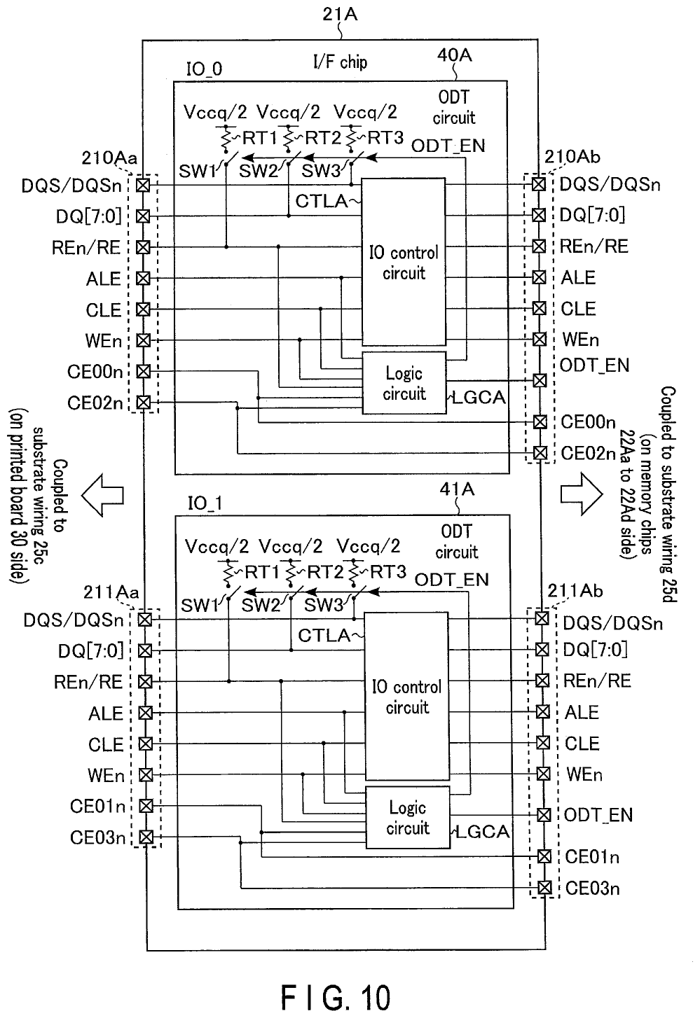

A circuit configuration of the I/F chips 21A respectively included in the packages 20AA and 20AB contained in the memory system 1A according to the present embodiment will be described with reference to FIG. 10. FIG. 10 is a circuit diagram showing an example of a configuration of the I/F chip 21A included in the package 20AA contained in the memory system 1A according to the present embodiment. The I/F chip 21A included in the package 20AB has a similar configuration to that of the I/F chip 21A in the package 20AA. Thus, a configuration of the I/F chip 21A in the package 20AA will be described hereinafter.

In the I/F chip 21A, input/output pin groups 210Ab and 211Ab each further include a signal pin used for transferring the signal ODT_EN. Hereinafter, the signal pin used for transferring the signal ODT_EN will be referred to as an “ODT pin”. The rest of the configuration of the I/F chip 21A is similar to that of the first embodiment.

The ODT pin of the input/output pin group 210Ab is coupled to the logic circuit LGCA of the ODT circuit 40A. The ODT pin of the input/output pin group 211Ab is coupled to the logic circuit LGCA of the ODT circuit 41A.

The logic circuit LGCA of the ODT circuit 40A transmits the signal ODT_EN to the ODT pin of the input/output pin group 210Ab. The signal ODT_EN transmitted to the input/output pin group 210Ab may be the same as the signal ODT_EN output to the plurality of switches SW1 to SW3. The logic circuit LGCA of the ODT circuit 41A transmits the signal ODT_EN to the ODT pin of the input/output pin group 211Ab. The signal ODT_EN transmitted to the input/output pin group 211Ab may be the same as the signal ODT_EN output to the plurality of switches SW1 to SW3.

[2-3] Circuit Configuration of Package 20AA

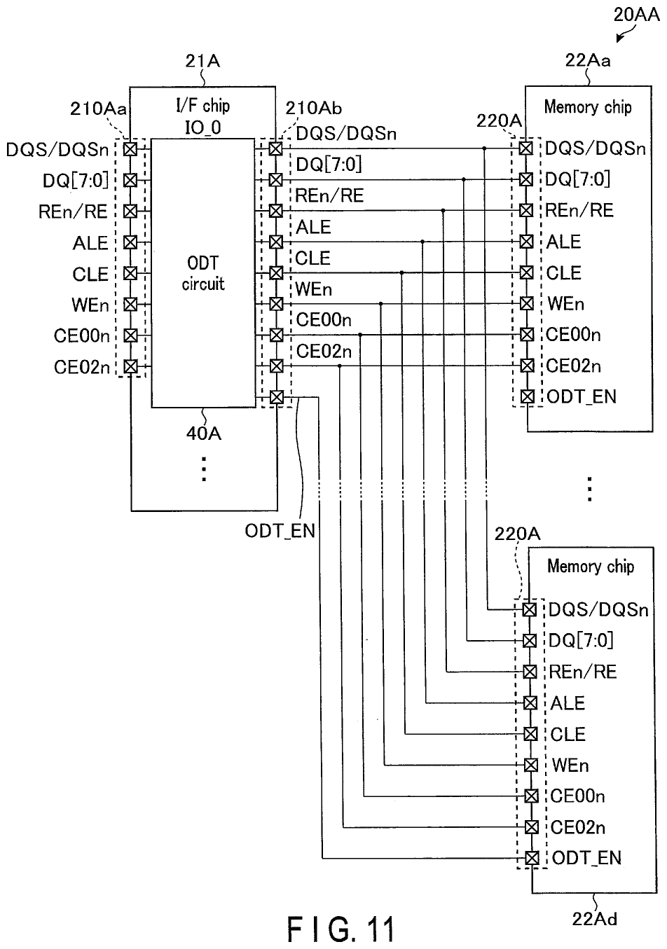

A circuit configuration of the package 20AA contained in the memory system 1A according to the present embodiment will be described with reference to FIG. 11. FIG. 11 is a circuit diagram showing an example of a configuration of the package 20AA contained in the memory system 1A according to the present embodiment. FIG. 11 omits the memory chips 22Ab and 22Ac coupled to the ODT circuit 40A included in the I/F chip 21A contained in the package 20AA. FIG. 11 omits the input/output pin groups 211Aa and 211Ab, and the ODT circuit 41A of the I/F chip 21A. FIG. 11 also omits the memory chips 22Aa to 22Ad coupled to the ODT circuit 41A. The package 20AB has a similar circuit configuration to that of the package 20AA. Thus, a circuit configuration of the package 20AA will be described hereinafter.

In each of the memory chips 22A coupled to the ODT circuit 40A, the input/output pin group 220A further contains an ODT pin. The ODT pin of the input/output pin group 210Ab is coupled to the ODT pin of the input/output pin group 220A of the memory chip 22Ad coupled to the ODT circuit 40A of the I/F chip 21A. The ODT pin of the input/output pin group 210Ab and the ODT pin of the memory chip 22Ad are coupled together via the interconnect 29. Coupling between the other signal pins of the input/output pin group 210Ab and the other signal pins of the input/output pin group 220A in each of the memory chips 22A coupled to the ODT circuit 40A is similar to that of the first embodiment. Each of the input/output pin groups 220A of the memory chips 22Aa to 22Ac coupled to the ODT circuit 40A does not necessarily have the ODT pin.

[2-4] Circuit Configuration of Memory Chip 22A

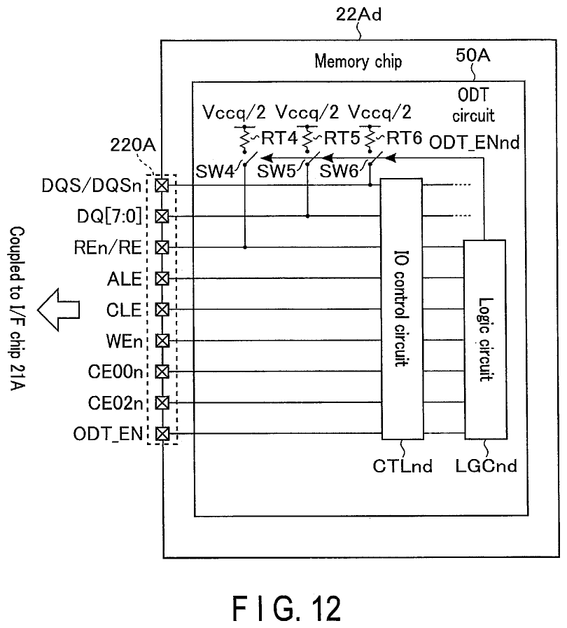

A circuit configuration of the memory chip 22A of the package 20AA contained in the memory system 1A according to the present embodiment will be described with reference to FIG. 12. FIG. 12 is a circuit diagram showing an example of a configuration of the memory chip 22Ad corresponding to the signal IO_0 of the package 20AA contained in the memory system 1A according to the present embodiment. The memory chips 22Aa to 22Ac corresponding to the signal IO_0 of the package 20AA and the memory chips 22Aa to 22Ad corresponding to the signal IO_1 of the package 20AA have similar configurations to that of the memory chip 22Ad corresponding to the signal IO_0 of the package 20AA. Thus, a configuration of the memory chip 22Ad corresponding to the signal IO_0 of the package 20AA will be described hereinafter.

The memory chip 22Ad further contains the ODT circuit 50A.

The input/output pin group 220A contains a plurality of signal pins. The plurality of signal pins of the input/output pin group 220A are coupled to the I/F chip 21A. As with the input/output pin group 210Ab of the I/F chip 21A, the plurality of signal pins of the input/output pin group 220A include a DQS pin, a DQ pin, an RE pin, an ALE pin, a CLE pin, a WE pin, a first CE pin, a second CE pin, and an ODT pin.

The ODT circuit 50A of the memory chip 22Ad corresponding to the signal IO_0 controls by using a termination resistor, reflection of a signal occurring between the input/output pin group 210Ab of the I/F chip 21A and the input/output pin group 220A of the memory chip 22Ad when a signal is input/output.

Hereinafter, “coupling (terminating) at least one signal pin of the input/output pin group 220A to the termination resistor” will also be expressed as “turning on the ODT circuit of the memory chip” or “executing the ODT operation by the ODT circuit of the memory chip”. On the other hand, “not coupling (not terminating) any signal pin of the input/output pin group 220A to the termination resistor” will also be expressed as “turning off or not turning on the ODT circuit of the memory chip” or “not executing the ODT operation by the ODT circuit of the memory chip”.

The ODT circuit 50A is coupled to the input/output pin group 220A. The ODT circuit 50A includes an IO control circuit CTLnd, a logic circuit LGCnd, a plurality of switches SW4, a plurality of switches SW5, a plurality of switches SW6, a plurality of resistance elements RT4, a plurality of resistance elements RT5, and a plurality of resistance elements RT6. To simplify the description, FIG. 12 illustrates one switch SW4, one switch SW5, one switch SW6, one resistance element RT4, one resistance element RT5, and one resistance element RT6.

The IO control circuit CTLnd is coupled to a DQS pin, a DQ pin, an RE pin, an ALE pin, a CLE pin, a WE pin, a first CE pin, a second CE pin, and an ODT pin of the input/output pin group 220A, and to the logic circuit LGCnd. The IO control circuit CTLnd receives signals DQS, DQSn, DQ, REn, RE, ALE, CLE, WEn, CE00, CE02, and ODT_EN from the input/output pin group 220A. The IO control circuit CTLnd adjusts a waveform of received signals from the input/output pin group 220A. The IO control circuit CTLnd transmits each of the adjusted signals to a later stage circuit (not shown). Furthermore, the IO control circuit CTLnd transmits the adjusted signals REn, RE, ALE, CLE, WEn, CE00, CE02, and ODT_EN to the logic circuit LGCnd.

The logic circuit LGCnd is an operation circuit. The logic circuit LGCnd is coupled to the IO control circuit CTLnd. The logic circuit LGCnd receives signals REn, RE, ALE, CLE, WEn, CE00n, CE02n, and ODT_EN from the IO control circuit CTLnd. The logic circuit LGCnd performs a logic operation based on each signal received from the IO control circuit CTLnd. In the case of the status 2 or 6 in FIG. 6, the logic circuit LGCnd outputs, as a signal ODT_ENnd, a signal obtained by inverting a logical level of the received signal ODT_EN, to the plurality of switches SW4 to SW6. On the other hand, in the case of a status other than the statuses 2 and 6 in FIG. 6, the logic circuit LGCnd outputs the received signal ODT_EN as the signal ODT_ENnd to the plurality of switches SW4 to SW6. The logic circuit LGCnd includes circuits such as, for example, an AND circuit, an OR circuit, a NAND circuit, a NOR circuit, and an EX-OR circuit. The logic circuit LGCnd performs a logic operation on a received signal by using these circuits in combination. The logic circuit LGCnd may output the signal ODT_ENnd based only on a logic of the received signal ODT_EN.

Each of the plurality of switches SW4 to SW6 is a switching element controlled based on the signal ODT_ENnd. Each of the switches SW4 to SW6 may be constituted by a transistor. Each of the plurality of resistance elements RT4 to RT6 functions as a termination resistor.

One end of the switch SW4 is coupled to the RE pin of the input/output pin group 220A. The other end of the switch SW4 is coupled to one end of the resistance element RT4. A voltage Vccq/2 is applied to the other end of the resistance element RT4.

One end of the switch SW5 is coupled to the DQ pin of the input/output pin group 220A. The other end of the switch SW5 is coupled to one end of the resistance element RT5. The voltage Vccq/2 is applied to the other end of the resistance element RT5.

One end of the switch SW6 is coupled to the DQS pin of the input/output pin group 220A. The other end of the switch SW6 is coupled to one end of the resistance element RT6. The voltage Vccq/2 is applied to the other end of the resistance element RT6.

In the case of the signal ODT_ENnd being at the “H” level, each of the switches SW4 to SW6 is turned to the ON state. By the switch SW4 being turned to the ON state, the RE pin of the input/output pin group 220A is terminated. By the switch SW5 being turned to the ON state, the DQ pin of the input/output pin group 220A is terminated. By the switch SW6 being turned to the ON state, the DQS pin of the input/output pin group 220A is terminated. That is, during a period in which the signal ODT_ENnd is at the “H” level, the ODT circuit 50A of the memory chip 22Ad is turned on. In other words, in the case of the signal ODT_ENnd being at the “H” level, the ODT circuit 50A of the memory chip 22Ad executes the ODT operation. On the other hand, in the case of the signal ODT_ENnd being at the “L” level, each of the switches SW4 to SW6 is turned to the OFF state. By each of the switches SW4 to SW6 being turned to the OFF state, each of the RE pin, the DQ pin, and the DQS pin of the input/output pin group 220A is not terminated. That is, during a period in which the signal ODT_ENnd is at the “L” level, the ODT circuit 50A of the memory chip 22Ad is not turned on. In other words, in the case of the signal ODT_ENnd being at the “L” level, the ODT circuit 50A of the memory chip 22Ad does not execute the ODT operation.

Signal pins to be terminated are not limited to the DQS pin, the DQ pin, and the RE pin.

[2-5] Non-Target ODT Operation

The memory system 1A according to the present embodiment performs the non-target ODT operation. The following will describe a case in which in the channel CH0, the memory controller 10 accesses the memory chip 22Ad out of the memory chips 22Aa to 22Ad corresponding to the signal IO_0 of the package 20AA, and does not access the memory chips 22Aa to 22Ad corresponding to the signal IO_1 of the package 20AB. A timing chart of the write operation accompanied with the non-target ODT operation is the same as that shown in FIG. 7. The timing chart of the read operation not accompanied with the non-target ODT operation is the same as that shown in FIG. 8.

First, the non-target ODT operation when performing the write operation will be described with reference to FIG. 7. In the present embodiment, the following operations are performed in addition to the operations described in the first embodiment.

During a period from time t2 to time t3, a signal input to the package 20AA on a selected side is in the status 6 shown in FIG. 6. Thus, in the memory chip 22Ad corresponding to the signal IO_0 of the package 20AA, the logic circuit LGCnd outputs, as the signal ODT_ENnd, a signal at the “H” level obtained by inverting a logical level of the signal ODT_EN at the “L” level received from the I/F chip 21A. By this, each of the switches SW4 to SW6 of the ODT circuit 50A of the memory chip 22Ad which is an access target is turned to the ON state. As a result, each of the DQS pin, the DQ pin, and the RE pin of the input/output pin group 220A of the memory chip 22Ad corresponding to the signal IO_0 of the package 20AA is terminated. That is, in the package 20AA on the selected side, the ODT circuit 50A of the memory chip 22Ad corresponding to the signal IO_0 is turned on.

During a period from time t2 to time t3, a signal input to the package 20AB on a non-selected side is in the status 2 shown in FIG. 6. Thus, in the memory chip 22Ad corresponding to the signal IO_1 of the package 20AB, the logic circuit LGCnd outputs, as the signal ODT_ENnd, a signal at the “L” level obtained by inverting a logical level of the signal ODT_EN at the “H” level received from the I/F chip 21A. By this, each of the switches SW4 to SW6 of the ODT circuit 50A of the memory chip 22Ad which is not an access target is turned to the OFF state. As a result, each of the DQS pin, the DQ pin, and the RE pin of the input/output pin group 220A of the memory chip 22Ad corresponding to the signal IO_1 of the package 20AB is not terminated. That is, in the package 20AB on the non-selected side, the ODT circuit 50A of the memory chip 22Ad corresponding to the signal IO_1 is not turned on.

During a period other than the above, the ODT circuit 50A of the memory chip 22Ad corresponding to the signal IO_0 is not turned on in the package 20AA while the ODT circuit 50A of the memory chip 22Ad corresponding to the signal IO_1 is not turned on in the package 20AB.

The non-target ODT operation when performing the read operation is similar to that in the first embodiment. When data is read, the ODT circuit 50A of the memory chip 22Ad corresponding to the signal IO_0 is not turned on in the package 20AA while the ODT circuit 50A of the memory chip 22Ad corresponding to the signal IO_1 is not turned on in the package 20AB.

[2-6] Advantageous Effect

The present embodiment has advantageous effects similar to those described in the first embodiment.

With the configuration according to the present embodiment, the input/output pin group 210Ab on the memory chip side of the I/F chip 21A has an ODT pin for transmitting the signal ODT_EN. The input/output pin group 220A of each of the memory chips 22Aa to 22Ad has an ODT pin for receiving the signal ODT_EN. Each of the memory chips 22Aa to 22Ad contains the ODT circuit 50A. The ODT circuit 50A controls an ODT operation in the corresponding memory chip 22A. The ODT pin of the I/F chip 21A is coupled to the ODT pin of the memory chip 22Ad in a position farthest from the I/F chip 21A. The ODT circuit 50A of the memory chip 22Ad is turned on based on the signal ODT_EN received from the I/F chip 21A with respect to the package to which the memory controller 10 accesses during the write operation. This configuration suppresses reflection of a signal from the memory chip 22Ad in a position farthest from the I/F chip 21A. Accordingly, operation reliability of the memory system 1A can be improved.

### [3] Modification, etc.

As described above, a memory system according to an embodiment includes: a first package (20A) including a first memory chip (22a/22b/22c/22d) configured to store data, and a first chip (21) containing a first circuit (40/41) configured to control an On Die Termination (ODT) operation based on a first signal (RE/REn) which is a control signal for reading of data stored in the first memory chip; a second package (20B) including a second memory chip (22a/22b/22c/22d) configured to store data, and a second chip (21) containing a second circuit (40/41) configured to control the ODT operation based on the first signal, the first signal also being a control signal for reading of data stored in the second memory chip; and a controller (10) configured to transmit the first signal to the first chip and the second chip.

The embodiments are not limited to those described in the above, and various modifications can be made.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A memory system comprising:
a first package including
a first memory chip configured to store data, and
a first chip containing a first circuit configured to control an On Die Termination (ODT) operation based on a first signal which is a control signal for reading of data stored in the first memory chip;
a second package including
a second memory chip configured to store data, and
a second chip containing a second circuit configured to control the ODT operation based on the first signal, the first signal also being a control signal for reading of data stored in the second memory chip; and
a controller configured to transmit the first signal to the first chip and the second chip.

2. The system according to claim 1, wherein in a case of a write operation with respect to the first memory chip, the first circuit of the first chip is configured not to execute the ODT operation, and the second circuit of the second chip is configured to execute the ODT operation.

3. The system according to claim 2, wherein in a case of a read operation with respect to the first memory chip, the first circuit of the first chip and the second circuit of the second chip are both configured not to execute the ODT operation.

4. The system according to claim 3,
wherein in the write operation, while the controller transmits address information along with the first signal to the first chip and the second chip, the first signal is at a first logical level, and
in the read operation, while the controller transmits address information along with the first signal to the first chip and the second chip, the first signal is at a second logical level different from the first logical level.

5. The system according to claim 1,
wherein the second chip further contains a first pin configured to receive the first signal and a second pin configured to receive another signal,
the second circuit further contains a third circuit, and a first resistance element and a first switching element that are coupled in series between the first pin or the second pin and a node configured to supply a power supply voltage with respect to the second circuit,
the third circuit is configured to transmit a fourth signal based on the first signal to the first switching element, and
the first switching element is configured to be controlled based on the fourth signal.

6. The system according to claim 5, wherein in a case of a write operation with respect to the first memory chip, the first switching element is configured to be controlled based on the fourth signal in such a manner as to be in a coupled state.

7. The system according to claim 5, wherein in a case of a read operation with respect to the first memory chip, the first switching element is configured to be controlled based on the fourth signal in such a manner as to be in a decoupled state.

8. The system according to claim 1,
wherein the first chip further contains a third pin configured to receive the first signal and a fourth pin configured to receive another signal,
the first circuit further contains a fourth circuit, and a second resistance element and a second switching element that are coupled in series between the third pin or the fourth pin and a node configured to supply a power supply voltage with respect to the first circuit,
the fourth circuit is configured to transmit a fifth signal based on the first signal to the second switching element, and
the second switching element is configured to be controlled based on the fifth signal.

9. The system according to claim 8, wherein in a case of a write operation with respect to the first memory chip, the second switching element is configured to be controlled based on the fifth signal in such a manner as to be in a decoupled state.

10. The system according to claim 8, wherein in a case of a read operation with respect to the first memory chip, the second switching element is configured to be controlled based on the fifth signal in such a manner as to be in a decoupled state.

11. The system according to claim 1, wherein the first memory chip and the second memory chip contain a circuit of a NAND flash memory.

12. The system according to claim 2,
wherein the second chip further contains a first pin configured to receive a first signal and a second pin configured to receive another signal,
the second circuit further contains a third circuit, and a first resistance element and a first switching element that are coupled in series between the first pin or the second pin and a node configured to supply a power supply voltage with respect to the second circuit,
the third circuit is configured to transmit a fourth signal based on the first signal to the first switching element, and
the first switching element is configured to be controlled based on the fourth signal.

13. The system according to claim 2, wherein the first memory chip and the second memory chip contain a circuit of a NAND flash memory.

14. The system according to claim 5, wherein the first memory chip and the second memory chip contain a circuit of a NAND flash memory.
